(19) United States
(12) Patent Application Publication
(10) Pub. No.: US 2026/0013248 A1
(43) Pub. Date: Jan. 8, 2026

(54) CMOS IMAGE SENSOR and Manufacturing Method Thereof

(71) Applicant: PixArt Imaging Incorporation, Hsinchu (TW)

(72) Inventors: Hsin-Hui Hsu, Hsinchu (TW); Yi-Fong Tseng, Hsinchu (TW); Chia-Yu Liu, Hsinchu (TW)

(21) Appl. No.: 18/765,650

(22) Filed: Jul. 8, 2024

(51) Int. Cl. H01L 27/146; G02B 1/115

(52) U.S. Cl. CPC H10F 39/805; G02B 1/115; H10F 39/024

(57) ABSTRACT

The present invention provides a CMOS image sensor and a manufacturing method thereof. The CMOS image sensor includes: a photodiode formed in a silicon substrate; and a multilayer dielectric formed on the silicon substrate, wherein the multilayer dielectric includes a plurality of dielectric layers sequentially stacked one on top of the other, and wherein the multilayer dielectric substantially covers an entire surface area of the photodiode; wherein a difference of two refractive indices between any two of the adjacent dielectric layers is less than a predetermined difference, thereby reducing photon reflection loss between the two adjacent dielectric layers to enhance a quantum efficiency of the photodiode.

### BACKGROUND OF THE INVENTION

### Field of Invention

The present invention relates to a CMOS image sensor. Particularly, it relates to such CMOS image sensor which can enhance a quantum efficiency. The present invention also relates to a manufacturing method of the CMOS image sensor.

### Description of Related Art

FIG. 1 shows a cross-sectional schematic diagram of a prior art CMOS image sensor. As shown in FIG. 1, a prior art CMOS image sensor 10 includes a photodiode 12 and a stack of layers on the photodiode 12. The stack includes a silicon dioxide layer 13, a silicon nitride layer 14, a silicon dioxide layer 15, and a silicon nitride layer 16 as shown in FIG. 1. When the CMOS image sensor 10 is integrated with conventional CMOS processes, as indicated by a gate GT, a plurality of contact plugs V1, a plurality of first metal lines M1, and a second metal line M2 shown in FIG. 1, it faces significant challenges. One primary issue encountered is related to the refractive indices of various materials involved in the CMOS fabrication process.

Still referring to FIG. 1, the silicon dioxide layer 13 is used as a block layer to prevent silicide formation during a Self-Aligned Silicide process step in conventional CMOS processes. The silicon nitride layer 14 serves as an etch stop layer during a contact etch process step. The silicon dioxide layer 15 is used as an interlayer dielectric (ILD) layer, and the silicon nitride layer 16 is used as a passivation layer. The stack of layers, including these layers, is formed during the integration process of the CMOS image sensor 10 with conventional CMOS processes.

The CMOS image sensor 10 is used to sense incident light LT1. The incident light LT1 passes through the aforementioned stack of layers before reaching the photodiode 12 as a refracted incident light LT2 indicated. In the atmosphere, the refractive index is relatively low. However, upon entering the CMOS image sensor 10, The incident light LT1 must traverse multiple layers of materials, such as the silicon nitride layer 16, the silicon dioxide layer 15, the silicon nitride layer 14, and the silicon dioxide layer 13, each with different refractive indices. This disparity in refractive indices causes the incident light LT1 to refract at varying degrees and results the refracted incident light LT2 in partial reflection. Consequently, a portion of the incident light fails to penetrate the stack of layers on the photodiode 12 effectively, and the Fresnel loss may reach approximately 30% due to the stack of layers on the photodiode 12.

In view of the above, the present invention proposes a CMOS image sensor and a manufacturing method thereof to overcome the drawbacks in the prior art.

### SUMMARY OF THE INVENTION

From one perspective, the present invention provides a CMOS image sensor, comprising: a photodiode formed in a silicon substrate; and a multilayer dielectric formed on the silicon substrate, wherein the multilayer dielectric includes a plurality of dielectric layers sequentially stacked one on top of the other, and wherein the multilayer dielectric substantially covers an entire surface area of the photodiode; wherein a difference of two refractive indices between any two of the adjacent dielectric layers is less than a predetermined difference, thereby reducing photon reflection loss between the two adjacent dielectric layers to enhance a quantum efficiency of the photodiode.

From another perspective, the present invention provides a manufacturing method of a CMOS image sensor, comprising: providing a silicon substrate; forming a photodiode in the silicon substrate; and forming a multilayer dielectric on the silicon substrate, wherein the multilayer dielectric includes a plurality of dielectric layers sequentially stacked one on top of the other, and wherein the multilayer dielectric substantially covers an entire surface area of the photodiode; wherein a difference of two refractive indices between any two of the adjacent dielectric layers is less than a predetermined difference, thereby reducing photon reflection loss between the two adjacent dielectric layers to enhance a quantum efficiency of the photodiode.

In one preferred embodiment, the plural refractive indices of the plural dielectric layers gradually increase from the topmost dielectric layer to the bottommost dielectric layer.

In one preferred embodiment, the predetermined difference is less than 0.3.

In one preferred embodiment, at least one of the dielectric layers of the multilayer dielectric is formed with a same process step in a manufacturing method of a CMOS device.

In one preferred embodiment, the dielectric layers include a silicon nitride layer (23), a silicon oxynitride layer (24), a silicon-rich oxide layer (25), and a silicon dioxide layer (26), wherein the silicon nitride layer (23), the silicon oxynitride layer (24), the silicon-rich oxide layer (25), and the silicon dioxide layer (26) are sequentially arranged from bottom to top, and each layer is connected to the adjacent layer.

In one preferred embodiment, the silicon nitride layer (23) is formed with a same process step of a spacer nitride layer in the manufacturing method of the CMOS device; wherein the silicon oxynitride layer (24) is formed with a same process step of a silicide block layer in the manufacturing method of the CMOS device; wherein the silicon-rich oxide layer (25) is formed with a same process step of a contact etch stop layer in the manufacturing method of the CMOS device; wherein the silicon dioxide layer (26) is formed with a same process step of an interlayer dielectric (ILD) layer in the manufacturing method of the CMOS device.

In one preferred embodiment, refractive indices of the silicon dioxide layer (26), the silicon-rich oxide layer (25), the silicon oxynitride layer (24), and the silicon nitride layer (23) are substantially 1.45, 1.6, 1.8, and 2 respectively.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-sectional schematic diagram of a prior art CMOS image sensor.

FIG. 2 shows a cross-sectional schematic diagram of an embodiment of a CMOS image sensor according to the present invention.

FIGS. 3A-3F are schematic diagrams showing a manufacturing method of a CMOS image sensor according to the present invention.

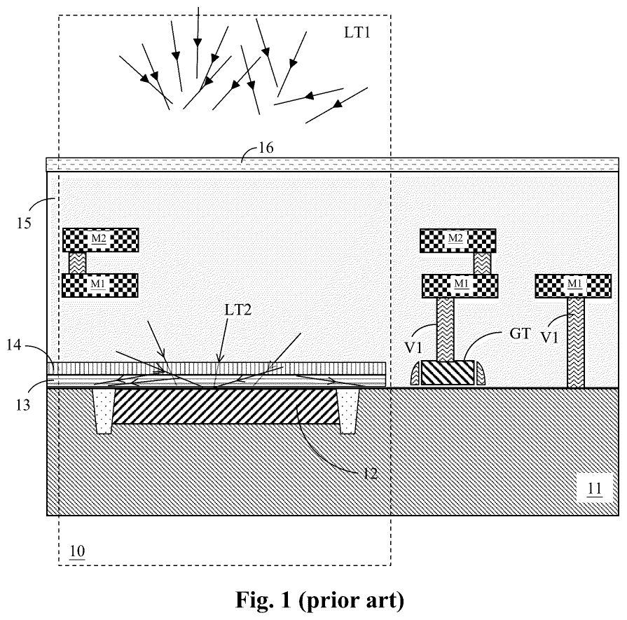

### DESCRIPTION OF THE PREFERRED EMBODIMENTS

The drawings as referred to throughout the description of the present invention are for illustration only, to show the interrelations between the regions and the process steps, but not drawn according to actual scale.

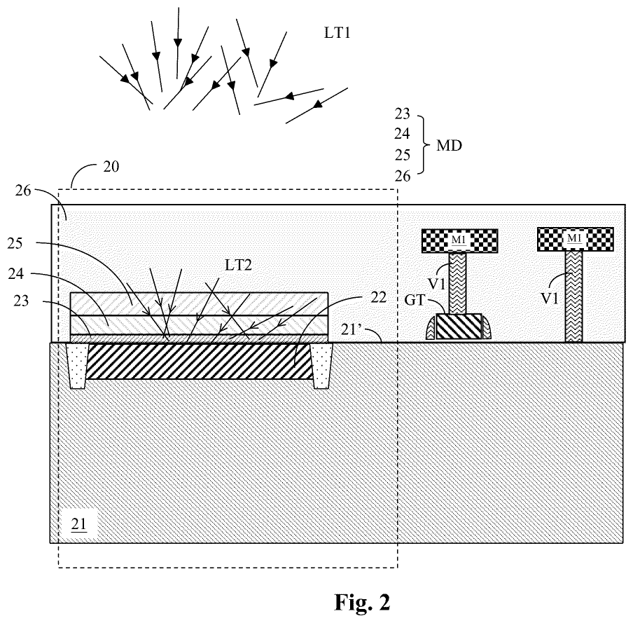

FIG. 2 shows a cross-sectional schematic diagram of a CMOS image sensor according to one embodiment of the present invention. As shown in FIG. 2, a CMOS image sensor 20 according to the present invention is configured to operably sense an incident light LT1. The CMOS image sensor 20 includes a photodiode 22 and a multilayer dielectric MD. The photodiode 22 is formed in a silicon substrate 21. In general, a photodiode is a semiconductor PN-junction structure sensitive to photon radiation, such as visible light, infrared or ultraviolet radiation, X-rays and gamma rays, it consumes radiation energy to produce an electric current. The photodiode can be designed to detect a wide range of wavelengths depending on the specific application, which may include but is not limited to imaging, communication, and sensing applications. In one embodiment, the silicon substrate 21 is for example but not limited to a P-type silicon substrate; and the photodiode 22 includes for example but not limited to an N-type well. The multilayer dielectric MD is formed on the substrate 21, wherein the multilayer dielectric MD includes a plurality of dielectric layers sequentially stacked one on top of the other, and wherein the multilayer dielectric MD substantially covers an entire surface area of the photodiode 22. In the CMOS image sensor 20, a difference of two refractive indices between any two of the adjacent dielectric layers is less than a predetermined difference, thereby reducing photon reflection loss between the two adjacent dielectric layers to enhance the quantum efficiency (QE) of the photodiode 22.

Still referring to FIG. 2, in one embodiment, the plural refractive indices of the plural dielectric layers gradually increase from the topmost dielectric layer to the bottommost dielectric layer.

In one embodiment, the plural refractive indices of the plural dielectric layers gradually increase from the topmost dielectric layer to the bottommost dielectric layer.

In one embodiment, the predetermined difference is less than 0.3.

In one embodiment, at least one of the dielectric layers of the multilayer dielectric is formed with a same process step in a manufacturing method of a CMOS device, as indicated by a gate GT, a plurality of contact plugs V1, a plurality of first metal lines M1 shown in FIG. 2.

As shown in FIG. 2, the multilayer dielectric MD includes the dielectric layers, from the bottommost dielectric layer to the topmost dielectric layer: a silicon nitride layer 23, a silicon oxynitride layer 24, a silicon-rich oxide layer 25, and a silicon dioxide layer 26 as shown in FIG. 2.

In one embodiment, the silicon nitride layer 23 is formed with a same process step of a spacer nitride layer in the manufacturing method of the CMOS device; the silicon oxynitride layer 24 is formed with a same process step of a silicide block layer in the manufacturing method of the CMOS device; the silicon-rich oxide layer 25 is formed with a same process step of a contact etch stop layer in the manufacturing method of the CMOS device; and the silicon dioxide layer 26 is formed with a same process step of an interlayer dielectric (ILD) layer in the manufacturing method of the CMOS device.

According to the present invention, in one embodiment, refractive indices of the silicon dioxide layer 26, the silicon-rich oxide layer 25, the silicon oxynitride layer 24, and the silicon nitride layer 23 are substantially 1.45, 1.6, 1.8, and 2 respectively.

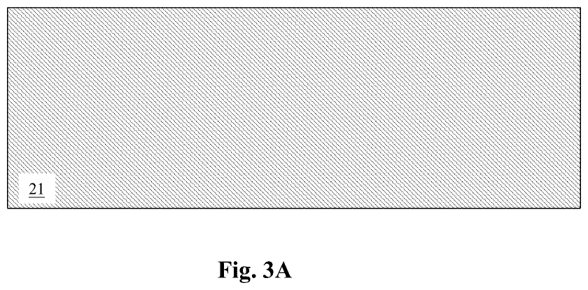

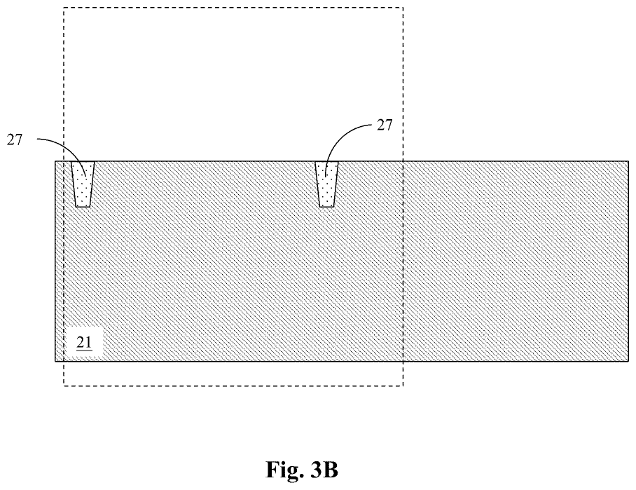

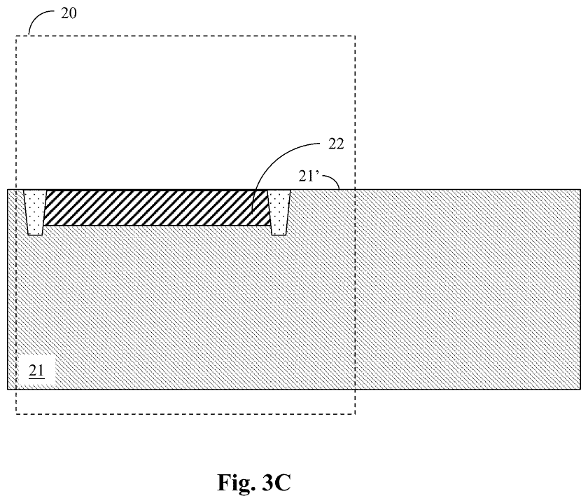

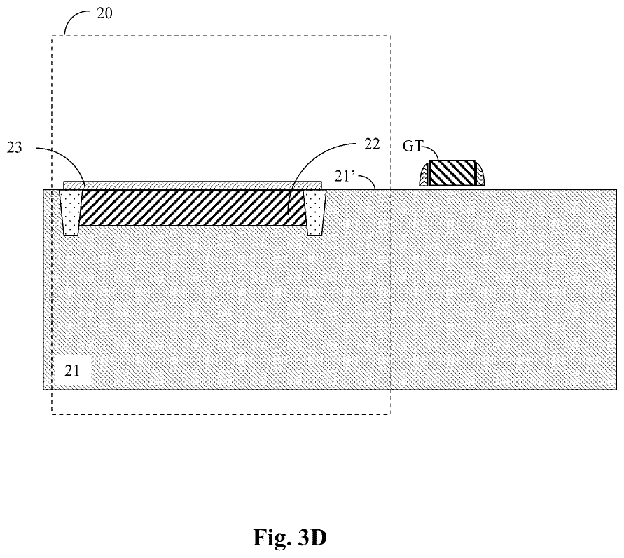

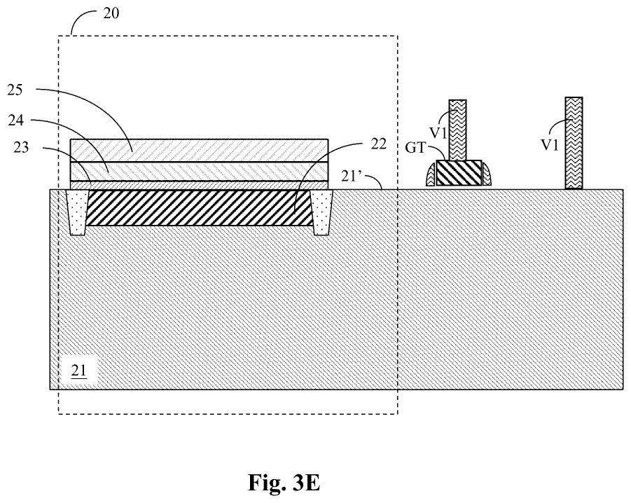

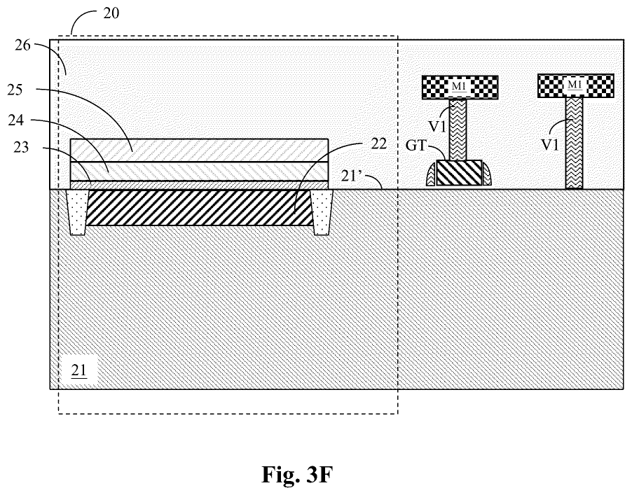

FIGS. 3A-3H are schematic diagrams showing a manufacturing method of the CMOS image sensor 20 according to the present invention.

First, as shown in FIG. 3A, a silicon substrate 21 is provided. In one embodiment, the silicon substrate 21 is a P-type silicon substrate.

Next, as shown in FIG. 3B, for example, insulation regions 27 are formed in the silicon substrate 21 to define the CMOS image sensor 20. The insulation regions 27 are configured to operably electrically isolate the CMOS image sensor 20 from other regions in the silicon substrate 21, and are for example but not limited to shallow trench isolation (STI) structures as shown in FIG. 3B.

Then, as shown in FIG. 3C, the photodiode 22 is formed in a silicon substrate 21. The photodiode 22 includes for example but not limited to a N-type well, and a PN junction is formed between the N-type well and the P-type silicon substrate.

Then, as shown in FIG. 3D, the silicon nitride layer 23 is formed on the photodiode 22, wherein the silicon nitride layer 23 covers the entire surface area of the photodiode 22. In one embodiment, the silicon nitride layer 23 is formed with a same process step of a spacer nitride layer in the manufacturing method of the CMOS device. As shown in FIG. 3D, the process step of forming the spacer nitride layer of the gate GT in the manufacturing method of the CMOS device also forms the silicon nitride layer 23 of the CMOS image sensor 20. In one embodiment, a thickness of the silicon nitride layer 23 is 20 nm, and a refractive index of the silicon nitride layer 23 is 2.

Then, as shown in FIG. 3E, the silicon oxynitride layer 24 is formed above the silicon nitride layer 23, wherein the silicon oxynitride layer 24 covers the entire surface area of the photodiode 22. In one embodiment, the silicon oxynitride layer 24 is formed with a same process step of a silicide block layer in the manufacturing method of the CMOS device. As shown in FIG. 3E, the process step of forming the silicide block layer in the manufacturing method of the CMOS device also forms the silicon oxynitride layer 24 of the CMOS image sensor 20. In one embodiment, a thickness of the silicon oxynitride layer 24 is 50 nm, and a refractive index of the silicon oxynitride layer 24 is 1.8.

Note that, in the manufacturing method of the CMOS device, the silicide block layer is used to prevent formation of silicide in undesired regions. The silicide block layer, made of silicon oxynitride in this embodiment, acts as a barrier during the Self-Aligned Silicide (SALICIDE) process. By selectively blocking silicide formation, the silicide block layer ensures that silicide is only formed on specific areas, such as source/drain regions and polysilicon gates, thereby improving the device performance and reliability.

Then, still referring to FIG. 3E, the silicon-rich oxide layer 25 is formed above and connected to the silicon oxynitride layer 24, wherein the silicon-rich oxide layer 25 covers the entire surface area of the photodiode 22. In one embodiment, the silicon-rich oxide layer 25 is formed with a same process step of a contact etch stop layer in the manufacturing method of the CMOS device. As shown in FIG. 3E, the process step of forming the contact etch stop layer in the manufacturing method of the CMOS device also forms the silicon-rich oxide layer 25 of the CMOS image sensor 20. In one embodiment, a thickness of the silicon-rich oxide layer 25 is 40 nm, and a refractive index of the silicon-rich oxide layer 25 is 1.6.

Note that, in the manufacturing method of the CMOS device, the contact etch stop layer (CESL) is utilized to control the etching process and protect underlying layers during contact formation. This layer, commonly made of silicon nitride, but silicon-rich oxide in this embodiment, acts as a barrier to prevent over-etching and damage to the underlying structures. By providing a precise etch stop point, the CESL ensures that the etching process creates accurate and clean contact holes, which are essential for forming reliable electrical connections of contact plugs V1 between different layers of the CMOS device. The contact etch stop layer thus plays a crucial role in maintaining the structural integrity and performance of the device. In this embodiment, the contact etch stop layer is made of silicon-rich oxide, for relatively lower refractive index compared to the silicon oxynitride layer 24, and for relatively higher refractive index compared to the silicon dioxide layer 26. Besides, the contact etch stop layer made of silicon-rich oxide still can act as a barrier to prevent over-etching and damage to the underlying structures.

Then, as shown in FIG. 3F, the silicon dioxide layer 26 is formed above the silicon-rich oxide layer 25, wherein the silicon dioxide layer 26 covers the entire surface area of the photodiode 22. In one embodiment, the silicon dioxide layer 26 is formed with a same process step of an interlayer dielectric (ILD) layer in the manufacturing method of the CMOS device. As shown in FIG. 3F, the process step of forming the ILD layer in the manufacturing method of the CMOS device also forms the silicon dioxide layer 26 of the CMOS image sensor 20. In one embodiment, a refractive index of the silicon dioxide layer 26 is 1.45.

Note that, in the manufacturing method of the CMOS device, the interlayer dielectric (ILD) is a crucial insulating layer that separates different metal layers (as indicated by the metal lines M1 shown in FIG. 2) and isolates them electrically. Typically made of materials such as silicon dioxide (SiO2), silicon nitride (Si3N4), or low-k dielectrics, the ILD provides both electrical insulation and mechanical support. During the CMOS fabrication process, the ILD is deposited after the formation of each metal layer to prevent short circuits and reduce capacitive coupling between the metal interconnects.

Because a refractive index of the silicon substrate 21 is 3.7, and the refractive indices of the plural dielectric layers (the silicon dioxide layer 26, the silicon-rich oxide layer 25, the silicon oxynitride layer 24, and the silicon nitride layer 23) gradually increase from the topmost dielectric layer (the silicon dioxide layer 26) to the bottommost dielectric layer the silicon nitride layer 23), the photon reflection loss will be reduced to enhance a quantum efficiency of the photodiode 22.

In summary, the present invention aims to minimize the differences in refractive indices between the adjacent layers of materials that light passes through before reaching the photodiode, particularly when the CMOS image sensor is integrated with the CMOS process. This approach of the present invention effectively reduces the quantum efficiency (QE) losses caused by light transitioning through different layers. The number and type of layers may vary according to the specific requirements of the CMOS process, but the core principle is to minimize the refractive index differences to enhance the quantum efficiency of the CMOS image sensor.

Additionally, according to the present invention, when light passes through the stack of layers before reaching the photodiode, it does not necessarily mean all layers stacked on the photodiode are involved. Instead, the present invention refers to the appropriate arrangement or selection of certain plural layers that can be integrated into the CMOS process. Furthermore, the invention allows for the adjustment of the refractive indices, arrangement, or selection of the stacked layers according to the application requirements, taking into account the differences in refractive indices of different wavelengths of light to be sensed in the same material. For example, when the photodiode is used to sense infrared light, the refractive indices, arrangement, or selection of the stacked layers can be adjusted specifically for the refractive index of infrared light in different materials. This adaptability ensures optimized performance for various applications by tailoring the stack of layers to the specific needs of different wavelengths of light.

The present invention has been described in considerable detail having reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. A CMOS image sensor, comprising:
a photodiode formed in a silicon substrate; and
a multilayer dielectric formed on the silicon substrate, wherein the multilayer dielectric includes a plurality of dielectric layers sequentially stacked one on top of the other, and wherein the multilayer dielectric substantially covers an entire surface area of the photodiode;
wherein a difference of two refractive indices between any two of the adjacent dielectric layers is less than a predetermined difference, thereby reducing photon reflection loss between the two adjacent dielectric layers to enhance a quantum efficiency of the photodiode.

2. The CMOS image sensor of claim 1, wherein the plural refractive indices of the plural dielectric layers gradually increase from the topmost dielectric layer to the bottommost dielectric layer.

3. The CMOS image sensor of claim 1, wherein the predetermined difference is less than 0.3.

4. The CMOS image sensor of claim 1, wherein at least one of the dielectric layers of the multilayer dielectric is formed with a same process step in a manufacturing method of a CMOS device.

5. The CMOS image sensor of claim 4, wherein the dielectric layers include a silicon nitride layer (23), a silicon oxynitride layer (24), a silicon-rich oxide layer (25), and a silicon dioxide layer (26), wherein the silicon nitride layer (23), the silicon oxynitride layer (24), the silicon-rich oxide layer (25), and the silicon dioxide layer (26) are sequentially arranged from bottom to top, and each layer is connected to the adjacent layer.

6. The CMOS image sensor of claim 5, wherein the silicon nitride layer (23) is formed with a same process step of a spacer nitride layer in the manufacturing method of the CMOS device;
wherein the silicon oxynitride layer (24) is formed with a same process step of a silicide block layer in the manufacturing method of the CMOS device;
wherein the silicon-rich oxide layer (25) is formed with a same process step contact etch stop layer in the manufacturing method of the CMOS device;
wherein the silicon dioxide layer (26) is formed with a same process step of an interlayer dielectric (ILD) layer in the manufacturing method of the CMOS device.

7. The CMOS image sensor of claim 6, wherein refractive indices of the silicon dioxide layer (26), the silicon-rich oxide layer (25), the silicon oxynitride layer (24), and the silicon nitride layer (23) are substantially 1.45, 1.6, 1.8, and 2 respectively.

8. A manufacturing method of a CMOS image sensor, comprising:
providing a silicon substrate;
forming a photodiode in the silicon substrate; and
forming a multilayer dielectric on the silicon substrate, wherein the multilayer dielectric includes a plurality of dielectric layers sequentially stacked one on top of the other, and wherein the multilayer dielectric substantially covers an entire surface area of the photodiode;
wherein a difference of two refractive indices between any two of the adjacent dielectric layers is less than a predetermined difference, thereby reducing photon reflection loss between the two adjacent dielectric layers to enhance a quantum efficiency of the photodiode.

9. The manufacturing method of claim 8, wherein the plural refractive indices of the plural dielectric layers gradually increase from the topmost dielectric layer to the bottommost dielectric layer.

10. The manufacturing method of claim 8, wherein the predetermined difference is less than 0.3.

11. The manufacturing method of claim 8, wherein at least one of the dielectric layers of the multilayer dielectric is formed with a same process step in a manufacturing method of a CMOS device.

12. The manufacturing method of claim 11, wherein the step of forming a multilayer dielectric on the silicon substrate includes:
forming a silicon nitride layer (23) on the photodiode 22, wherein the silicon nitride layer (23) covers the entire surface area of the photodiode;
forming a silicon oxynitride layer (24) above and connected to the silicon nitride layer (23), wherein the silicon oxynitride layer (24) covers the entire surface area of the photodiode;
forming a silicon-rich oxide layer (25) above and connected to the silicon oxynitride layer (24), wherein the silicon-rich oxide layer (25) covers the entire surface area of the photodiode; and
forming a silicon dioxide layer (26) above and connected to the silicon-rich oxide layer (25), wherein the silicon dioxide layer (26) covers the entire surface area of the photodiode;
wherein the silicon nitride layer (23), the silicon oxynitride layer (24), the silicon-rich oxide layer (25), and the silicon dioxide layer (26) are sequentially arranged from bottom to top, and each layer is connected to the adjacent layer.

13. The manufacturing method of claim 12, wherein the silicon nitride layer (23) is formed with a same process step of a spacer nitride layer in the manufacturing method of the CMOS device;
wherein the silicon oxynitride layer (24) is formed with a same process step of a silicide block layer in the manufacturing method of the CMOS device;
wherein the silicon-rich oxide layer (25) is formed with a same process step of a contact etch stop layer in the manufacturing method of the CMOS device;
wherein the silicon dioxide layer (26) is formed with a same process step of an interlayer dielectric (ILD) layer in the manufacturing method of the CMOS device.

14. The manufacturing method of claim 13, wherein refractive indices of the silicon dioxide layer (26), the silicon-rich oxide layer (25), the silicon oxynitride layer (24), and the silicon nitride layer (23) are substantially 1.45, 1.6, 1.8, and 2 respectively.
